(19) United States
(12) Patent Application Publication
(10) Pub. No.: US 2007/0241939 A1
(43) Pub. Date: Oct. 18, 2007

(54) Projection apparatus and key input device thereof

(75) Inventors: Nan-Jiun Yin, Miao-Li (TW); Yen-Hsien Su, Miao-Li (TW)

Correspondence Address: BACON & THOMAS, PLLC, 625 SLATERS LANE, FOURTH FLOOR, ALEXANDRIA, VA, 22314, US

(73) Assignee: CORETRONIC CORPORATION, Hsinchu (TW)

(21) Appl. No.: 11/652,585

(22) Filed: Jan. 12, 2007

(30) Foreign Application Priority Data
Apr. 13, 2006 (TW) 95113236

(51) Int. Cl. H03M 11/00

(52) U.S. Cl. 341/22

(57) ABSTRACT

A projection apparatus includes a projecting module, a key input device and a controlling unit. The projecting module generates an image light beam. The key input device includes a key unit and a decoding conversion unit coupled to the key unit. The key unit includes a plurality of keys. When at least one of the keys is pressed, the decoding conversion unit outputs an identifying signal to the key unit and performs a decoding operation according to the identifying signal sent back from the key unit, and outputs a controlling signal to the controlling unit accordingly. The controlling unit coupled to the projecting module is for receiving the controlling signal and driving the projecting module accordingly.

This application claims the benefit of Taiwan application Serial No. 95113236, filed Apr. 13, 2006, the subject matter of which is incorporated herein by reference.

### BACKGROUND OF THE INVENTION

1. Field of the Invention

The invention relates in general to a projection apparatus and a key input device thereof, and more particularly to a projection apparatus and a key input device, which uses a decoding conversion unit to decode a key identifying signal and output a controlling signal accordingly, thereof.

2. Description of the Related Art

FIG. 1 is a schematic illustration showing a conventional projector 100. Referring to FIG. 1, the projector 100 includes a main body 10 which has a projecting module 104 and a controlling Integrated Circuit (IC) 103. The projector 100 further includes a key input panel 101. The projecting module 104 generates an image light beam to display an image onto a screen (not shown). When receiving a projection signal, the controlling IC 103 drives the projecting module 104 to generate the image light beam.

The key input panel 101 includes a plurality of keys 102 typically functioning as switches. Each key 102 has a first terminal 102a coupled to a grounding voltage and a second terminal 102b coupled to one of the General Purpose Input/Output (GPIO) ports p of the controlling IC 103. When the keys 102 are not pressed, each GPIO port p is held at a high voltage level.

As shown in FIG. 1, when a user presses the corresponding key 102 to execute some function of the projector 100, the first terminal 102a and the second terminal 102b of the key 102 are electrically coupled to each other through the pressing operation, and the corresponding GPIO port p instantaneously drops to the grounding voltage. Thus, the controlling IC 103 performs the desired functional operation control according to the GPIO port p with a voltage change. When the user ends the pressing operation, the corresponding GPIO port p again returns to the original high voltage level. Thus, the controlling IC 103 determines the user's desired function and correspondingly controls the projecting module 104 by detecting a voltage change of each GPIO port p.

However, the number of keys 102 on the key input panel 101 gradually increases with the trend toward the multi-function design of the projector. Each key 102 needs a corresponding GPIO port p. Such that the number of the GPIO ports p of the controlling IC 103 has to be greater than or equal to that of the keys 102. However, the number of the GPIO ports p of the controlling IC 103 is limited, and the GPIO ports p are insufficient when the number of keys 102 is over the limit. Thus, it is a bottleneck of the current projector to improve the insufficiency of the GPIO ports p.

### SUMMARY OF THE INVENTION

Other objectives, features and advantages of the present invention will be further understood from the further technology features disclosed by the present invention wherein there is shown and described a preferred embodiment of this invention, simply by way of illustration of one of the modes best suited to carry out the invention.

It is therefore one, more or all of object of the invention to provide a projection apparatus and a key input device thereof. The key input device has a decoding conversion unit to decode a key identifying signal and output a controlling signal accordingly, such that a controlling unit of the projection apparatus receives the controlling signal through a specific General Purpose Input/Output (GPIO) port to perform the functional operation control without increasing the number of the GPIO ports.

The invention achieves the above-identified object by providing a key input device used in a projection apparatus. The projection apparatus includes a controlling unit. The key input device includes a key unit and a decoding conversion unit coupled to the key unit. The key unit includes a plurality of keys. When at least one of the keys is pressed, the decoding conversion unit outputs an identifying signal to the key unit and then performs a decoding operation according to the identifying signal sent back from the key unit. The decoding conversion unit outputs a controlling signal to the controlling unit accordingly.

The invention also achieves the above-identified object by providing a projection apparatus. The projection apparatus includes a projecting module, a key input device and a controlling unit. The projecting module generates an image light beam. The key input device includes a key unit and a decoding conversion unit coupled to the key unit. The key unit includes a plurality of keys. When at least one of the keys is pressed, the decoding conversion unit outputs an identifying signal to the key unit and performs a decoding operation according to the identifying signal sent back from the key unit. The decoding conversion unit outputs a controlling signal to the controlling unit accordingly. The controlling unit coupled to the projecting module is for receiving the controlling signal and driving the projecting module accordingly.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 is a schematic illustration showing a conventional projector.

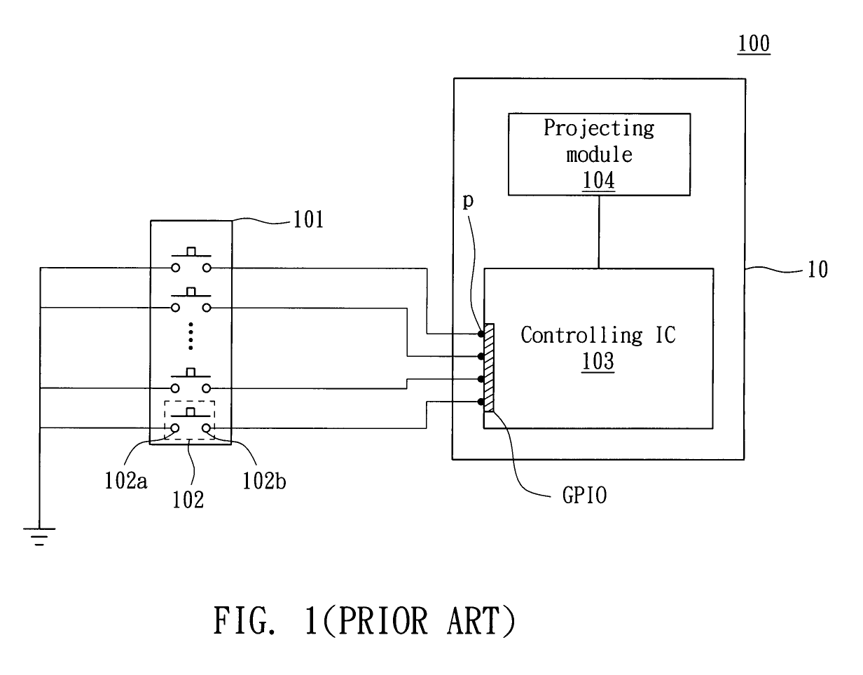

FIG. 2 is a schematic block diagram showing a projection apparatus according to a preferred embodiment of the invention.

FIG. 3 shows a circuit structure of a projection apparatus according to a first embodiment of the invention.

FIG. 4 shows a circuit structure of a projection apparatus according to a second embodiment of the invention.

FIG. 5 is a schematic block diagram showing a projection apparatus according to a third embodiment of the invention.

### DETAILED DESCRIPTION OF THE INVENTION

Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. In addition, the terms “connected” and “coupled” and variations thereof are not restricted to physical or mechanical connections or couplings.

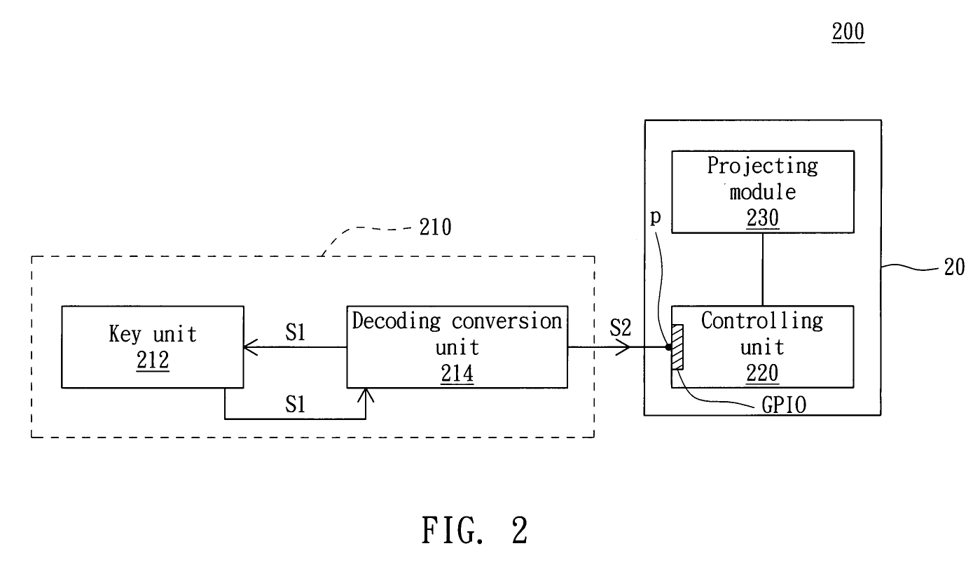

FIG. 2 is a schematic block diagram showing a projection apparatus 200 according to a preferred embodiment of the invention. Referring to FIG. 2, the projection apparatus 200 includes a main body 20 which has a projecting module 230 and a controlling unit 220. The projection apparatus 200 further includes a key input device 210. The key input device 210 includes a key unit 212 and a decoding conversion unit 214 coupled to the key unit 212. The projecting module 230 generates an image light beam. The projecting module 230 is coupled to the controlling unit 220. When receiving a projection signal, the controlling unit 220 drives the projecting module 230 to generate the image light beam. When the user presses at least one of the keys of the key unit 212, the decoding conversion unit 214 outputs an identifying signal S1 to the key unit 212. Then, the decoding conversion unit 214 performs a decoding operation according to the identifying signal S1 sent back from the key unit 212 and then outputs a controlling signal S2 to the controlling unit 20. The controlling unit 220, such as a Central Processing Unit (CPU), is coupled to the decoding conversion unit 214 and receives the controlling signal S2 through a specific GPIO port p to execute the corresponding functional operation control on the projecting module 230, such that the projecting module 230 generates the desired image light beam.

### First Embodiment

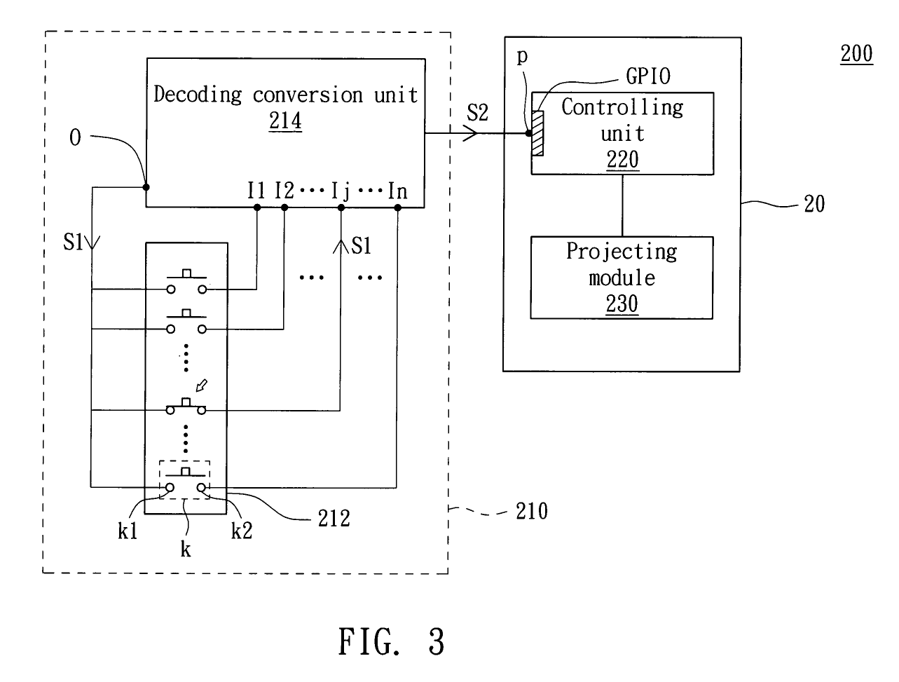

FIG. 3 shows a circuit structure of the projection apparatus 200 according to a first embodiment of the invention. Referring to FIG. 3, the key unit 212 of the projection apparatus 200 is a keypad row switching device including n keys k, such as a power key, a screen function display key, and the like. The n is a positive integer. The decoding conversion unit 214 includes an output port O and a plurality of input ports I1 to In. The output port O is coupled to a first terminal k1 of each key k, and each of the input ports I1 to In is correspondingly coupled to a second terminal k2 of each key k. When a user presses a j^{th} key k, for example, as indicated by the arrow of FIG. 3, the first terminal k1 and the second terminal k2 of the key k are electrically coupled to each other through the pressing operation. Meanwhile, the identifying signal S1 is outputted from the output port O to the key k, which is ON, and then the key unit 212 sends the identifying signal S1 to the corresponding input port Ij through the key k. The decoding conversion unit 214 performs the decoding operation according to the input port Ij through which the identifying signal S1 is received by the decoding conversion unit 214, and thus outputs the controlling signal S2 to the General Purpose Input/Output (GPIO) port p of the controlling unit 220. The controlling unit 220 further executes the corresponding key function control according to the received controlling signal S2, and drives the projecting module 230 to generate the desired image light beam. Thus, the key input device 210 only needs one GPIO line coupled to one GPIO port of the controlling unit 220 to achieve the object of key input control.

### Second Embodiment

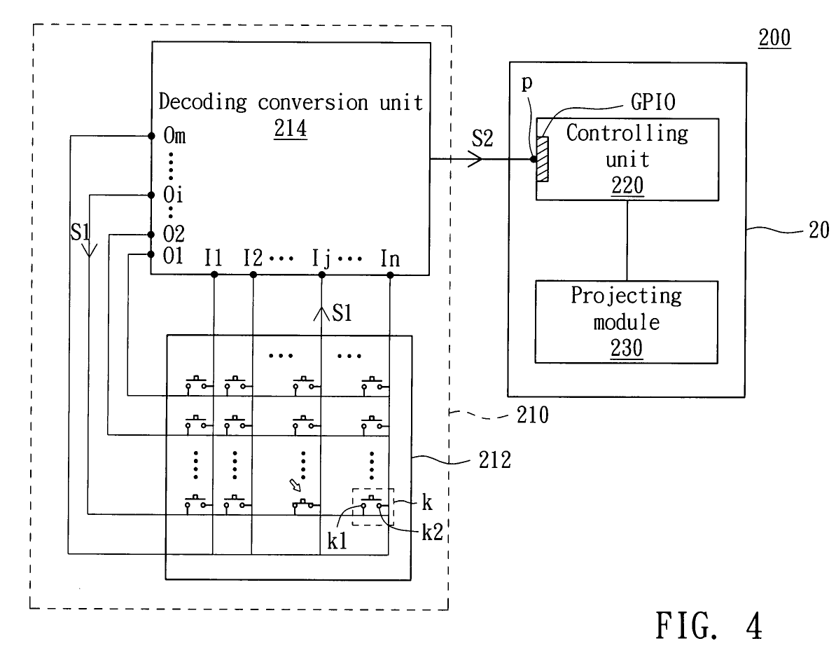

FIG. 4 shows a circuit structure of the projection apparatus 200 according to a second embodiment of the invention. As shown in FIG. 4, the key unit 212 of the projection apparatus 200 is a keypad matrix switching device including m×n keys k. The m and n are positive integers. The decoding conversion unit 214 includes m output ports O1 to Om and n input ports 11 to In. The output ports O1 to Om are respectively coupled to first terminals k1 of first to m^{th} rows of keys k, and the input ports I1 to In are correspondingly coupled to second terminals k2 of first to n^{th} columns of keys k. When the user presses the key k at the i^{th} row and the j^{th} column, for example, as indicated by the arrow of FIG. 4, the first terminal k1 and the second terminal k2 of the key k are electrically coupled to each other through the pressing operation. Meanwhile, the identifying signal S1 is outputted from the corresponding output port Oi to the key k, which is ON, and the key unit 212 sends the identifying signal S1 to the corresponding input port Ij through the key k. The decoding conversion unit 214 performs the decoding operation according to the output port Oi from which the identifying signal S1 is outputted by the decoding conversion unit 214 and the input port Ij through which the identifying signal S1 is received by the decoding conversion unit 214, and thus outputs the controlling signal S2 to the GPIO port p of the controlling unit 220. The controlling unit 220 further executes the corresponding key function control according to the controlling signal S2 and drives the projecting module 230 to generate the desired image light beam. Thus, the key input device 210 is coupled to one GPIO port of the controlling unit 220 through only one GPIO line to achieve the object of multi-key input control.

The decoding conversion unit 214 in the first and second embodiments is, for example, a remote control transmitter integrated circuit (IC) and has eight address pins. That is, it is possible to provide 2⁸=256 address combinations (i.e., 8-bit command code) according to two logic states (ON and OFF) of each address pin. Thus, the remote control transmission IC can identify 256 ON combinations of output ports and input ports, and thus output accordingly the controlling signal containing the corresponding command code and other transmission codes, such as a lead code and a data code, to inform the controlling unit 220 to execute the instruction of the user. The numbers of the output ports and the input ports are adjusted according to the type of the key switch. For example, one output port corresponds to at most 256 input ports (e.g., n=256 in FIG. 3) to match with 256 one-dimensional key switches to execute the key input control. Alternatively, it is possible to adopt m output ports corresponding to n input ports to match with various m×n keypad matrix switches, wherein m×n≦256, such as the 4×8 or 16×16 keypad matrix switches (m and n may respectively equal to 4 and 8, or 16 and 16 in FIG. 4). More particularly, when the projection apparatus 200 has the expended function such as copy, fax and the DVD player, the number of keys of the key unit 212 is usually increased greatly. Thus, the key input device 210 of the invention adopts the design of the decoding conversion unit 214 to avoid the problem of the insufficient GPIO ports of the controlling unit 220 in the prior art because the key input device 210 can be coupled to one specific GPIO port of the controlling unit 220 through only one GPIO line. Meanwhile, the manufacturing cost of the projection apparatus 200 is reduced. If the number of the address pins in the remote control transmitter integrated circuit is increased, more key instructions can be correspondingly identified.

### Third Embodiment

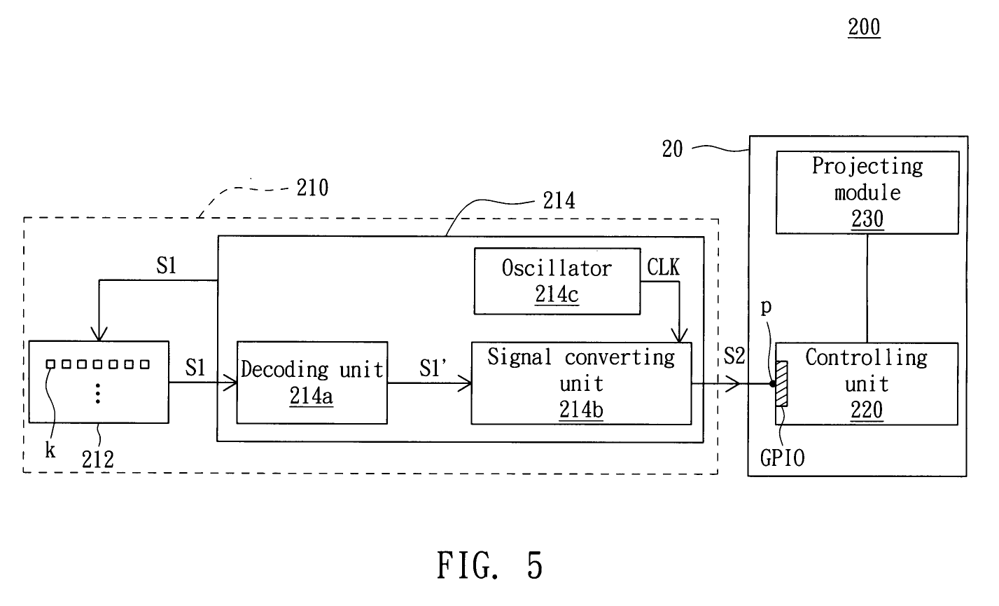

FIG. 5 is a schematic block diagram showing the projection apparatus according to a third embodiment of the invention. As shown in FIG. 5, the key unit 212 of the projection apparatus 200, such as a keypad row or a keypad matrix, includes a plurality of keys k. When the user presses one of the keys k, the key unit 212 sends the corresponding identifying signal S1, which carries the functional operation data (such as the combinations of output ports and input ports described above) defined by the pressed key k. The decoding conversion unit 214 further includes a decoding unit 214a, a signal converting unit 214b and an oscillator 214c. The decoding unit 214a coupled to the key unit 212 performs the decoding operation according to the identifying signal S1 to generate setting data such as the corresponding command code and other transmission codes and thus outputs the decoding signal S1′ accordingly. The signal converting unit 214b coupled to the decoding unit 214a converts the decoded signal S1′ according to a clock signal CLK provided by the oscillator 214c, and then outputs accordingly the controlling signal S2, which contains the corresponding command code and other transmission codes such as the lead code and the data code, meanwhile the format of the controlling signal S2 could be accepted by the controlling unit 220. The controlling unit 220 further executes the corresponding key function control according to the controlling signal S2 and drives the projecting module 230 to generate the desired image light beam. Consequently, the key input device 210 can be coupled to one GPIO port of the controlling unit 220 through only one GPIO line to achieve the object of multi-key input control and the manufacturing cost of the projection apparatus 200 is reduced.

Of course, one of ordinary skill in the art may easily understand that the invention is not restricted to the described three embodiments. Any modification of the key input device 210 for decoding the key identifying signal into the controlling signal S2 and outputting the controlling signal S2 to one specific GPIO port of the controlling unit 220 to achieve the object of multi-key input control by the design of the decoding conversion unit 214 still falls within the range of the invention.

In the projection apparatus and the key input device thereof according to the embodiment of the invention, the decoding conversion unit disposed in the key input device can decode the key identifying signal, and the controlling signal can be transferred to one specific GPIO port of the controlling unit to achieve the object of multi-key input control through only one GPIO line. Thus, it is possible to prevent the prior art problem of the insufficient GPIO ports of the controlling unit when the number of the keys is increased. In addition, the projection apparatus of the invention only use the decoding conversion unit to replace the great number of GPIO transmission lines, thereby reducing the manufacturing cost of the projection apparatus more effectively.

The foregoing description of the preferred embodiment of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like is not necessary limited the claim scope to a specific embodiment, and the reference to particularly preferred exemplary embodiments of the invention does not imply a limitation on the invention, and no such limitation is to be inferred. The invention is limited only by the spirit and scope of the appended claims. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A key input device used in a projection apparatus, the projection apparatus comprising a controlling unit, the key input device comprising:
a key unit comprising a plurality of keys; and
a decoding conversion unit coupled to the key unit, wherein when at least one of the keys is pressed, the decoding conversion unit outputs an identifying signal to the key unit and performs a decoding operation according to the identifying signal sent back from the key unit, and outputs a controlling signal to the controlling unit accordingly.

2. The apparatus according to claim 1, wherein the key unit includes a keypad row switching device and the decoding conversion unit comprises:
an output port coupled to the keys, wherein the identifying signal is outputted from the output port; and
a plurality of input ports correspondingly coupled to the keys;
wherein when at least one of the keys is pressed, the identifying signal is outputted from the output port to the key, the key unit sends the identifying signal to a corresponding input port through the key, and the decoding conversion unit performs the decoding operation according to the corresponding input port.

3. The apparatus according to claim 1, wherein the key unit comprises a keypad matrix switching device and the decoding conversion unit comprises:
a plurality of output ports correspondingly coupled to the keys; and
a plurality of input ports correspondingly coupled to the keys;
wherein when at least one of the keys is pressed, the identifying signal is outputted from a corresponding output port to the key, the key unit sends the identifying signal to a corresponding input port through the key, and the decoding conversion unit performs the decoding operation according to the corresponding output port and the corresponding input port.

4. The apparatus according to claim 1, wherein the decoding conversion unit uses a remote control transmitter integrated circuit (IC).

5. The apparatus according to claim 1, wherein the decoding conversion unit comprises:
a decoding unit coupled to the key unit, for performing the decoding operation according to the identifying signal, and outputting a decoding signal accordingly; and
a signal converting unit coupled to the decoding unit, for converting the decoding signal and outputting the controlling signal accordingly.

6. The apparatus according to claim 5, wherein the decoding conversion unit comprises an oscillator for providing a clock signal, and the signal converting unit outputs the controlling signal according to the clock signal.

7. A projection apparatus, comprising:
a projecting module for generating an image light beam; and
a key input device comprising:
a key unit comprising a plurality of keys; and
a decoding conversion unit coupled to the key unit, wherein when at least one of the keys is pressed, the decoding conversion unit outputs an identifying signal to the key unit and performs a decoding operation according to the identifying signal sent back from the key unit, and outputs a controlling signal to the controlling signal accordingly; and
a controlling unit coupled to the projecting module, for receiving the controlling signal and driving the projecting module accordingly.

8. The apparatus according to claim 7, wherein the controlling unit receives the controlling signal through a General Purpose Input/Output (GPIO) port.

9. The apparatus according to claim 7, wherein the key unit comprises a keypad row switching device and the decoding conversion unit comprises:
an output port coupled to the keys, wherein the identifying signal is outputted from the output port; and
a plurality of input ports correspondingly coupled to the keys;
wherein when at least one of the keys is pressed, the identifying signal is outputted from the output port to the key, the key unit sends the identifying signal to a corresponding input port through the key, and the decoding conversion unit performs the decoding operation according to the corresponding input port.

10. The apparatus according to claim 7, wherein the key unit comprises a keypad matrix switching device and the decoding conversion unit comprises:
a plurality of output ports correspondingly coupled to the keys; and
a plurality of input ports correspondingly coupled to the keys;
wherein when at least one of the keys is pressed, the identifying signal is outputted from a corresponding output port to the key, the key unit sends the identifying signal to a corresponding input port through the key, and the decoding conversion unit performs the decoding operation according to the corresponding output port and the corresponding input port.

11. The apparatus according to claim 7, wherein the decoding conversion unit uses a remote control transmitter integrated circuit.

12. The apparatus according to claim 7, wherein the decoding conversion unit comprises:
a decoding unit coupled to the key unit, for performing the decoding operation according to the identifying signal, and outputting a decoding signal accordingly; and
a signal converting unit coupled to the decoding unit, for converting the decoding signal and outputting the controlling signal accordingly.

13. The apparatus according to claim 12, wherein the decoding conversion unit further comprises an oscillator for providing a clock signal, and the signal converting unit outputs the controlling signal according to the clock signal.

14. The apparatus according to claim 7, wherein the controlling unit is a central processing unit (CPU).
